(19) United States
(12) Patent Application Publication
(10) Pub. No.: US 2020/0250354 A1
(43) Pub. Date: Aug. 6, 2020

(54) BUILDING INFORMATION MODELING SYSTEM WITH SELF-CONFIGURATION

(71) Applicant: Oshkosh Corporation, Oshkosh, WI (US)

(72) Inventors: Neil Doherty, Oshkosh, WI (US); James Hahessy, Oshkosh, WI (US)

(73) Assignee: Oshkosh Corporation, Oshkosh, WI (US)

(21) Appl. No.: 16/781,816

(22) Filed: Feb. 4, 2020

Related U.S. Application Data
(60) Provisional application No. 62/801,630, filed on Feb. 5, 2019.
(60) Provisional application No. 62/826,635, filed on Mar. 29, 2019.

(51) Int. Cl. G06F 30/13; G06Q 50/08

(52) U.S. Cl. CPC G06F 30/13; G06Q 50/08

(57) ABSTRACT

A method for automatically configuring a building information model (BIM) includes receiving a first data model and a second data model. The first data model includes construction site data and a three-dimensional model of a construction site. The second data model includes construction equipment data and a three-dimensional model of the construction equipment. The method further includes determining one or more tasks to be completed from the first data model and determining one or more pieces of construction equipment capable of completing the one or more tasks based on a comparison between the first data model and the second data model.

### CROSS-REFERENCE TO RELATED APPLICATIONS

This application claims the benefit of U.S. Provisional Application No. 62/801,630, filed Feb. 5, 2019, and U.S. Provisional Application No. 62/826,635, filed Mar. 29, 2019, both of which are incorporated herein in their entireties.

### BACKGROUND

To meet time and budget constraints, construction projects often require many different processes to happen simultaneously. Such processes can include construction tasks (e.g., laying concrete, placing supports, wiring, painting, etc.), movement of construction equipment into, out of, and throughout the construction site, shipment of building materials to the construction site, and removal of waste from the construction site. If these processes are not carefully managed, conflict can occur between the processes, increasing costs and delays to the construction project. Building information modeling (BIM) systems are used to represent various elements of the construction project digitally to facilitate planning of the various construction processes.

### SUMMARY

At least one embodiment of present disclosure relates to a method for automatically configuring a building information model (BIM). The method includes receiving a first data model. The first data model includes construction site data and a three-dimensional model of a construction site. The method further includes receiving a second data model. The second model includes construction equipment data and a three-dimensional model of the construction equipment. The method further includes determining one or more tasks to be completed from the first data model and determining one or more pieces of construction equipment capable of completing the one or more tasks based on a comparison between the first data model and the second data model.

Another embodiment of the present disclosure relates to a building information model (BIM) system for automatically configuring a building model. The system includes a processing circuit that includes one or more processors and memory. The memory stores instructions that, when executed by the one or more processors, cause the one or more processors to perform operations. The operations include receiving a first data model, the first data model comprising construction site data and a three-dimensional model of a construction site. The operations further include receiving a second data model, the second model comprising construction equipment data and a three-dimensional model of the construction equipment. The operations further include determining one or more tasks to be completed from the first data model. The operations further include determining one or more pieces of construction equipment capable of completing the one or more tasks based on a comparison between the first data model and the second data model.

Another embodiment of the present disclosure relates to a building information management device for automatically configuring a building model. The device includes a processing circuit that includes one or more processors and memory. The memory stores instructions that, when executed by the one or more processors, cause the one or more processors to perform operations. The operations include receiving a first data model, the first data model comprising construction site data and a three-dimensional model of a construction site. The operations further include receiving a second data model, the second model comprising construction equipment data and a three-dimensional model of the construction equipment. The operations further include determining one or more tasks to be completed from the first data model. The operations further include determining one or more pieces of construction equipment capable of completing the one or more tasks based on a comparison between the first data model and the second data model.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

### BRIEF DESCRIPTION OF THE DRAWINGS

The disclosure will become more fully understood from the following detailed description, taken in conjunction with the accompanying figures, wherein like reference numerals refer to like elements, in which:

FIG. 1 is a block diagram of a BIM system, according to an exemplary embodiment.

FIG. 2 is a detailed block diagram of the BIM system of FIG. 1, according to an exemplary embodiment.

FIG. 3 is a three-dimensional model of a building that may be generated by the BIM system of FIG. 1, according to an exemplary embodiment.

FIG. 4 is a two-dimensional model of a construction site that may be generated by the BIM system of FIG. 1, according to an exemplary embodiment.

FIG. 5 is a three-dimensional model of a building that may be generated by the BIM system of FIG. 1, according to an exemplary embodiment.

FIG. 6 is a detailed three-dimensional model of a scissor lift entering a construction site that may be generated by the BIM system of FIG. 1, according to an exemplary embodiment.

FIG. 7 is a detailed three-dimensional model of a scissor lift that may be generated by the BIM system of FIG. 1, according to an exemplary embodiment.

FIG. 8 is a three-dimensional model of a boom lift that may be generated by the BIM system of FIG. 1, according to an exemplary embodiment.

FIG. 9A is a graph that shows various operational parameters for a boom lift that may be generated by the BIM system of FIG. 1, according to an exemplary embodiment.

FIG. 9B is a graph that shows various operational parameters for a boom lift that may be generated by the BIM system of FIG. 1, according to an exemplary embodiment.

FIG. 9C is a data model that shows various operational parameters for a boom lift that may be generated by the BIM system of FIG. 1, according to an exemplary embodiment.

FIG. 10A is a three-dimensional model of a building that may be generated by the BIM system of FIG. 1, according to an exemplary embodiment.

FIG. 10B is a data model that shows various operational parameters for a boom lift that may be generated by the BIM system of FIG. 1, according to an exemplary embodiment.

FIG. 10C is a graph that shows various operational parameters for a boom lift that may be generated by the BIM system of FIG. 1, according to an exemplary embodiment.

FIG. 11 is a block diagram of a process that may be performed by the BIM system of FIG. 1, according to an exemplary embodiment.

FIG. 12 is a block diagram of a process that may be performed by the BIM system of FIG. 1, according to an exemplary embodiment.

FIG. 13 is a block diagram of a process that may be performed by the BIM system of FIG. 1, according to an exemplary embodiment.

### DETAILED DESCRIPTION

Before turning to the figures, which illustrate the exemplary embodiments in detail, it should be understood that the present application is not limited to the details or methodology set forth in the description, illustrated in the figures, or described in attached Appendix A. It should also be understood that the terminology is for the purpose of description only and should not be regarded as limiting.

### Overview

Throughout the life of a construction project, various pieces of construction equipment are required to perform various tasks at different times. In some systems, building equipment or construction equipment is requested (e.g., ordered, rented, etc.) as construction processes require the equipment, and the equipment is ordered to suit the specific process. However, when the construction equipment required to complete a certain process is not identified in advance, the construction project may encounter certain obstacles that delay the project. By way of example, a lift device having a certain threshold reach may be required to complete a certain task in a specific room of a building. In order for construction equipment having the threshold reach to reach that room, the construction equipment may be required to travel along a certain path (e.g., because that path is the only path offering doorways large enough to accommodate the equipment). However, the weight of the construction equipment may be greater than what the floor along that path may be able to support. If this constraint is not identified in advance, a delay may be experienced while the floor is reinforced. If the constraint is identified in advance, the reinforcement of the floor may be completed at a time that does not introduce delays into the project.

Oftentimes when modeling a construction project, the user may be unfamiliar with the various parameters for the model. For example, the user modeling a construction project may want to use a lift device, but may be unfamiliar with the boom extensions and boom angles. The user may have limited, or basic, understanding of the machine operation needed to perform the desired functions. Without familiarity of the construction equipment, the user may construct a construction project with configurations such that the real machine cannot achieve the configurations. Therefore, it may be desirable to simplify the modeling experience for the user to ensure achievable configurations with the desired pieces of construction equipment to achieve a behavior.

According to an exemplary embodiment, a building information modeling (BIM) system is configured to link available BIM data relating to a construction project (e.g., a model of a construction site, a schedule of when certain construction processes should be completed) with equipment data (e.g., parameters and three-dimensional models of various types of construction equipment). The BIM system is configured to analyze the linked BIM data and determine a construction equipment recommendation. The construction equipment recommendation may include the type, model, and quantity of construction equipment that should be provided, the specific time periods during which the equipment is required, and the routes that the equipment should take to access the areas in which the corresponding construction processes will be performed.

According to another exemplary embodiment, building information modeling is a framework to generate and manage the digital representations of physical and functional characteristics of construction projects. The purpose of BIM may be to deliver client capital expenditure (CapEx) and operational expenditure (OpEx) through various methods, including a clear common set of asset deliverables, early definition of design and knowledge of how the project is being build, increased industrialization (e.g., modular construction), early issue detection through data construction modeling and simulation, early clear building management strategy, and data rich modeling to plan renovations or demolitions. The purpose of BIM may be to supply data rich machine models to architects, civil engineers, and contractors through the construction design and planning phases.

According to another embodiment, the BIM may incorporate virtual construction and operation planning. This may include early issue identification and telematics (e.g., real time data), on time construction readiness data, and on time construction status. The BIM may digitally link machine application data to the BIM construction data enabling planners and resource managers to automatically select and optimise machine needs. As projects requirements change, the system may automatically update requirements and alert planners to any machine resource constraints earlier in the planning cycle. Implementing the BIM system disclosed herein can identify solutions/issues early, avoid costly onsite delays, and provide detailed method statements for construction projects.

### Building Information Modeling Systems

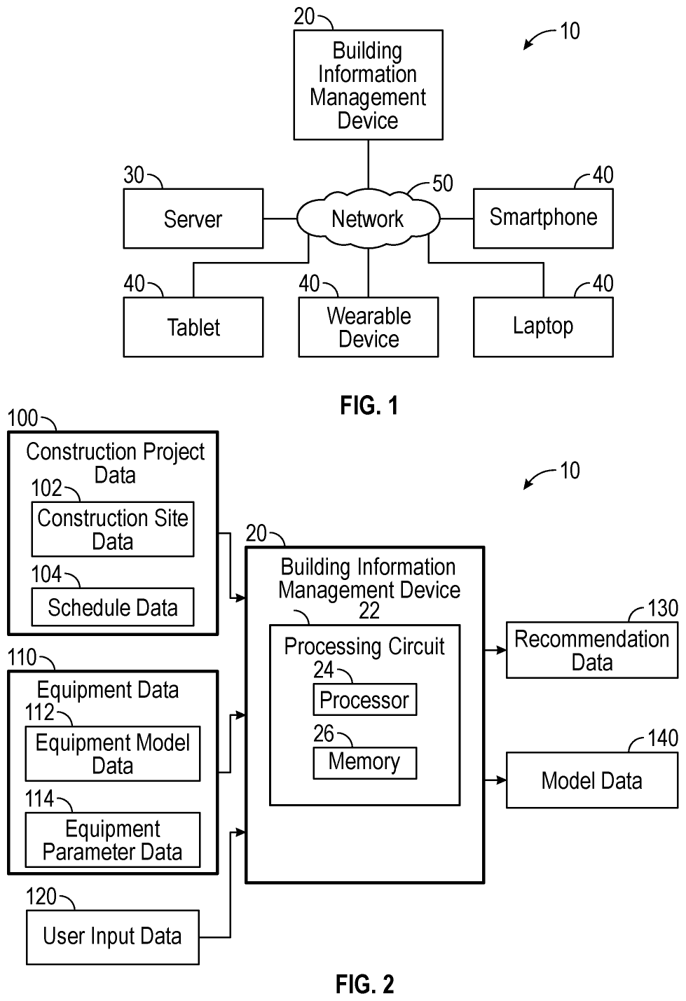

Referring now to FIG. 1, a building information management system (BIM) system 10 is shown, according to an exemplary embodiment. BIM system 10 includes building information management device 20, server 30, tablet 40, wearable device 40, laptop 40, smartphone 40, and network 50. BIM system 10 may provide various modeling software from one or more servers (e.g., server 30) to one or more building modeling devices (e.g., building information management device 20) via network 50. BIM system 10 may be located within a cloud, such that the various BIM applications are received by building information management device 20 as software as a service (i.e., SaaS). BMI system 10 can be partially or wholly configured as an infrastructure as a service (i.e., IaaS) or platform as a service (i.e., PaaS). BMI system 10 may receive the required applications for modeling from one or more servers that may be located on-premise or off-premise (i.e., located on hardware in a different building). BIM system 10 may be configured to generate an intelligent three-dimensional model for various construction needs. The model may include various information relating to the logistics, specifications, and other parameters relating to the construction of the model (e.g., building model). This information may be combined with the design components of the model to generate predictive analyses and facilitate proper and efficient testing.

Building information management device 20 may be configured to receive BIM data related to a project (e.g., construction project, building construction project, etc.) from various sources (e.g., over a network, the cloud, etc.), analyze the BIM data, and provide recommendations or other outputs (e.g., construction equipment recommendations) based on the analysis of the BIM data. For example, building information management device 20 may receive information regarding the working height of a scissor lift. In such an example, the working height of the scissor lift is 38 feet. Building information management device 20 may also receive information relating to the construction project, such as the height wall height of one of the walls within the building, which is 45 feet. Both sets of information (e.g., scissor lift information and wall height information) may be provided to building information management device 20 for analysis. Building information management device 20 is disclosed in further detail below with reference to FIG. 2.

In an exemplary embodiment, building information management device 20 determines a specific piece of construction equipment that has the attributes (e.g., capacities, physical properties, etc.) required to complete a specific construction process (e.g., a scissor lift having a range of 30 feet is required). Alternatively, the building information management device 20 may determine a range of different construction equipment that has the attributes required to perform a specific construction process (e.g., a piece of construction equipment capable of lifting an operator at least 30 feet above the ground). Such a range may include multiple types of construction equipment (e.g., boom lifts, scissor lifts, and vertical lifts, etc.).

Server 30 may be configured to store information relating to building equipment, equipment data, construction project data, or any other information that may be required by BIM system 10. Server 30 can be any type of information storage (e.g., server, FTP server, database server, etc.) located either on-premises (i.e., on a server within the same building as building information management device 20) or off-premises, or within the cloud (e.g., SaaS, IaaS, etc.) In some embodiments, server 30 is populated with information relating to construction project data and equipment data, and is provided to building information management device 20. In other embodiments, server 30 stores any and all information relating to BIM system 10. The building information management device 20 includes a controller or processing circuit 22. The processing circuit 22 includes a processor 20 and a memory 24. The building information management device 20 may include one or more servers, user devices (e.g., personal computers, smartphones, tablets, wearable devices, etc.), or other types of devices. In some embodiments, the building information management device 20 is a single device. In other embodiments, the building information management device 20 includes multiple devices.

Devices 40 (i.e., tablet 40, wearable device 40, laptop 40, and smartphone 40) may be any devices connected to network 50 such that information regarding BIM system 10 may be provided/received via network 50. Devices 40 may be configured to receive status updates, notifications regarding the building model progress, alarms, or other signals to one or more users of devices 40. Devices 40 may also include processing that allows them to provide instructions to building information management device 20. For example, a user (e.g., design engineer) may provide data for building information management device 20 that is not already stored on server 30 or retrieved via network 50 from an external source (not shown in FIG. 1).

Referring now to FIG. 2, a detailed block diagram of building information management system (BIM) system 10 is shown, according to an exemplary embodiment. BIM system 10 is shown to include building information management device 20, construction project data 100, equipment data 110, user input data 120, recommendation data 130, and model data 140. BIM system 10 may be configured to receive various information regarding a construction project (e.g., construction project data 100, equipment data 110, etc.) and provide analytical data (e.g., model data 140, recommendation data 130) to one or more users (e.g., engineers, designers, etc.) for modeling a building.

In an exemplary embodiment, BIM system 10 as shown in FIG. 2 may be incorporated into BIM system 10 shown in FIG. 1. Building information management device 20, as shown in FIG. 2, may receive information from construction project data 100, equipment data 110, and user input data 120. This information may be received from server 30 and/or devices 40, as shown in FIG. 1. Particularly, construction project data 100 and equipment data 110, may be received from server 30, while user input data 120 is received by one or more devices 40.

Building information management device 20 may be identical or similar to building information management device 20 as disclosed with reference to FIG. 1. In exemplary embodiments, building information management device 20 is configured to receive first input data or BIM data, shown as construction project data 100, and second input data or BIM data, shown as equipment data 110. In some embodiments, the building information management device 20 is additionally configured to receive third input data, shown as user input data 120, as shown in FIG. 2. Construction project data 100, equipment data 110, and user input data 120 may be received by one or more of server 30 and/or devices 40. In other embodiments, construction project data 100, equipment data 110, and/or user input data 120 are provided to the building information management device 20 via instructions through a user interface from a user device (i.e., devices 40).

In an exemplary embodiment, building information management device 20 is configured to analyze the input data (i.e., construction project data 100, equipment data 110, and user input data 120). Based on the analysis of the input data, the building information management device 20 is configured to provide first output data, shown as recommendation data 130, and second output data or BIM data, shown as model data 140. The output data may be provided over network 50 to various users via devices 40 and/or to various other devices (not shown in FIGS. 1-2). The output data may be used to inform other decisions (e.g., of a user, of another device, etc.) throughout the construction project and/or during maintenance of a structure subsequent to completion of the structure.

In another exemplary embodiment, building information management device 20 is configured to communicate with one or more other devices to receive the BIM data (e.g., input data) and provide the recommendations or other outputs (e.g., to a user). As shown in FIG. 1, the building information management device 20 is configured to communicate with (e.g., provide output data to, receive BIM data from, etc.) a first device, shown as server 30, and a series of second devices, shown as user devices 40 (e.g., personal computers, smartphones, tablets, wearable devices, etc.). These devices may be configured to receive inputs from one or more users, store information, and/or display information to one or more users. In other embodiments, the BIM system 10 includes more, fewer, or alternative devices. As shown, the server 30 and the user devices 40 communicate with the building information management device 20 through a network 50 (e.g., a local area network, a wide area network, the Internet, etc.). In other embodiments, the server 30 and/or the user devices 40 communicate directly with the building information management device 20.

Building information management device 20 is shown to include processing circuit 22. Processing circuit 22 may be implemented as a general-purpose processor, an application specific integrated circuit (ASIC), one or more field programmable gate arrays (FPGAs), a digital-signal-processor (DSP), circuits containing one or more processing components, circuitry for supporting a microprocessor, a group of processing components, or other suitable electronic processing components.

Processing circuit is shown to include processor 24 and memory 26. Processor 24 may include an ASIC, one or more FPGAs, a DSP, circuits containing one or more processing components, circuitry for supporting a microprocessor, a group of processing components, or other suitable electronic processing components. In some embodiments, processor 24 is configured to execute computer code stored in the memory 26 to facilitate the activities described herein. The memory 26 may be any volatile or non-volatile computer-readable storage medium capable of storing data or computer code relating to the activities described herein. According to an exemplary embodiment, memory 26 includes computer code modules (e.g., executable code, object code, source code, script code, machine code, etc.) configured for execution by the processor 24. In some embodiments, processing circuit 22 represents a collection of processing devices (e.g., servers, data centers, etc.). In such cases, processor 24 represents the collective processors of the devices, and memory 26 represents the collective storage devices of the devices.

Still referring to FIG. 2, construction project data 100 can include any information relating to the specifications, constraints, demands, or goals of the construction project. In an exemplary embodiment construction project data 100 includes the location, dimensions, timeline, cost, and various other information for construction a building. Construction project data 100 is shown to include construction site data 102 and schedule data 104.

In an exemplary embodiment, construction project data 100 may include an indication of a type of construction equipment that will be required. By way of example, the construction project data 100 may indicate that a light fixture should be installed in the gymnasium, and that this process will require a scissor lift having a reach of at least 30 feet. Additionally or alternatively, the construction project data 100 may include data related to the construction process, and the building information management device 20 may analyze the data to determine what type of construction equipment will be required. By way of example, the construction project data 100 may indicate that a light fixture should be installed in a gymnasium and may indicate that the light fixture will be 30 feet off of the ground. The building information management device 20 may determine that a scissor lift having a reach of at least 30 feet would be appropriate for installing the light fixture. Alternatively, if the construction project data 100 indicates that there is an obstacle directly below the light fixture, the building information management device 20 may determine that a boom lift is required to avoid interfacing with the obstacle.

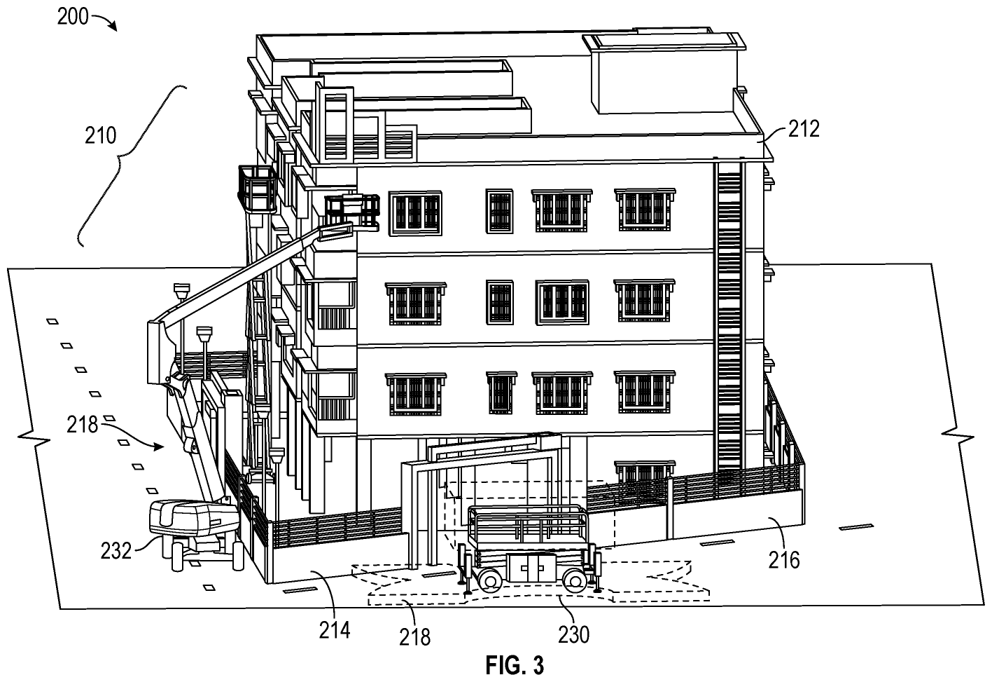

Construction site data 102 may include some or all data relating to a construction site. Construction site data 102 can include a three-dimensional model of the construction site. The three-dimensional model may show land (e.g., the topography of land), natural features (e.g., rivers, mountains, rocks, etc.), structures (e.g., walls, buildings, roads, bridges, fences, etc.), or other features of the construction site. The three-dimensional model may show the construction site at a beginning, intermediate, or completed stage of the project. In some embodiments, the three-dimensional model can be viewed at multiple stages of the project. By way of example, the construction site data 102 may include a different version of the three-dimensional model corresponding to each day, week, or month of the project. Details regarding the modeling and analytics of the construction site data 102 is described in greater detail below with reference to FIGS. 3-5.

In an exemplary embodiment, construction site data 102 includes data relating to various properties of different parts of the construction site 210, as shown in FIG. 3. Such properties can include, but are not limited to, size (e.g., length, width, height, etc.), weight, material, structural properties (e.g., load capacity of a surface or structure, stress-strain curves for different materials, etc.), cost, or other properties.

Schedule data 104 may include planned dates, times, locations, and associated resources (e.g., personnel, material, equipment, etc.) for certain events (e.g., construction processes). Schedule data may include scheduling information relating to scheduling of the labor, timeline schedule of the project, or any other time-sensitive aspect of the construction project. By way of example, the schedule data 104 may include the date, time, location, and the resources required to wire a certain subsystem of a building.

Still referring to FIG. 2, equipment data 110 includes data that relates to the characteristics of one or more pieces of construction equipment (e.g., engine powered boom lifts, electric boom lifts, hybrid boom lifts, vertical lifts, stock pickers, scissor lifts, towable boom lifts, etc.). The construction equipment may be involved in performing one or more construction processes. By way of example, the construction equipment may move workers, materials, waste, or other equipment to, from, or throughout a construction site. By way of another example, the construction equipment may be involved in performing one or more construction tasks (e.g., laying concrete, placing supports, wiring, painting, etc.). In some embodiments, the construction equipment can include lift devices (e.g., boom lifts, telehandlers, scissor lifts, vertical lifts, stock pickers, cranes, etc.). In some embodiments, the construction equipment can include earth moving devices (e.g., dump trucks, end loaders, backhoes, tractors, etc.). In some embodiments, the construction equipment can include concrete mixing and/or hauling devices (e.g., concrete mixer trucks, batch plants, etc.). In some embodiments, the construction equipment can include other devices that move material, equipment, waste, and/or personnel (e.g., semi-trailer trucks, flat-bed trucks, refuse vehicles, utility task vehicles, etc.). In other embodiments, the construction equipment can include other types of vehicles or equipment.

In an exemplary embodiment, equipment data 110 is provided by a manufacturer of the equipment. For example, manufacturer ABC of an electric boom lift may provide the platform capacity and machine width to BIM system 10. BIM system 10 may store the platform capacity and machine width of the electric boom width (i.e., equipment data 110) within server 30, as shown in FIG. 1. In other embodiments, equipment data 110 is measured by one or more users (e.g., construction site laborers, technicians, engineers, etc.) after manufacturing, either prior to or after the equipment arriving on the construction site. For example, a technician that works for manufacturer ABC may test an electric boom lift to determine the equipment data (e.g., platform capacity, machine width, etc.). The technician may then provide that information to BIM system 10 via network 50.

Equipment data 110 is shown to include equipment model data 112 and equipment parameter data 114. Equipment model data 112 can include various models (e.g., conceptual, logical, physical, etc.) in either two-dimensions or three-dimensions of the construction equipment. For example, equipment model data 112 my include several data elements A, B, and C. Data element A includes the data relating to the size of an electric boom lift, data element B includes the data relating to the weight of the lift, and data element C includes the data relating to the operational parameters of the lift. Combining these data elements into an abstract formalization creates a data model (e.g., data structure) for the electric boom lift. Further examples of similar models for equipment data 110 are described below with reference to FIGS. 3-11.

Equipment parameter data 114 can include any parameters that specify (e.g., qualify or quantify) the performance of the construction equipment or the equipment itself. The equipment parameter data 114 can include dimensions of the equipment (e.g., length, width, height, etc.), weight, axle oscillation, engine type, fuel tank capacity, payload capacity, ground clearance, drive speed, turning radius, ground bearing pressure, hydraulic fluid tank capacity, tire type and size, gradeability, lifting time, or other parameters.

User input data 120 can include commands, instructions, or information that is provided by a user (e.g., construction site laborer, technician, engineer, etc.). User input data 120 may be provided through a user interface of the building information management device 20 or of another device. The user input data 120 may be used to control the building information management device 20 and/or to modify other input data. User input data 120 may be received by devices 40 via network 50, as shown in FIG. 1.

In an exemplary embodiment, user input data 120 includes various instructions for combining certain elements of equipment data 110 with certain elements of construction project data 100 to facilitate the generation of building analytics and/or building modeling. For example, a user may provide user input data 120 via network 50 to compare the equipment model data 112 for a scissor lift with the required height and load capacity for the task of installing drywall on 20-feet wall. Building information management device 20 may then determine if the scissor lift is capable of completing the task and update the user accordingly.

Still referring to FIG. 2, recommendation data 130 can include recommendations or commands generated by the building information management device 20 based on the analysis of the input data. The recommendation data 130 can include recommendations of construction equipment to use (e.g., a type or model of equipment, a source of the equipment, etc.) and paths for the construction equipment to take through a construction site to reach an area where a construction process is to be completed. Recommendation data 130 can include recommendations for modifications to a schedule for the construction project. Recommendation data 130 can include purchase orders (e.g., a request to a rental company to rent a certain piece of equipment on a certain day, etc.).

Model data 140 can include a three-dimensional model (e.g., the model 200) that shows both a construction site (the construction site 210) and construction equipment (e.g., the scissor lift 230, the boom lift 232, etc.) within the construction site. The model data 140 may be viewed by a user through a user interface of the building information management device 20 or through a user interface of another device. Additionally or alternatively, the model data 140 may be used to perform other analysis. The model data 140 may show paths for the construction equipment to take through the construction site. The model data 140 may show how various aspects of the construction equipment (e.g., the work envelope 240, the turning radius 242, etc.) interact with other elements of the construction site (e.g., the building 212, the fence 216, etc.).

### BIM Model Examples

Referring generally to FIGS. 3-8 various models of a construction site are shown, according to exemplary embodiments. In an exemplary embodiment, FIGS. 3-8 disclose various systems and methods for determining whether pieces of construction equipment (e.g., boom lifts, scissor lifts, etc.) are capable of entering a doorway of a construction site using BIM. In an exemplary embodiment, the various models disclosed herein may be generated by building information management device 20. Construction project data 100 provides project model data and equipment data 110 provides equipment model data to building information management device.

Referring now to FIG. 3, a three-dimensional model 200 of a building that may be generated by the BIM systems of FIGS. 1-2 is shown, according to an exemplary embodiment. Model 200 is shown to include construction site 210. Construction site 210 is shown to include building 212, foundation 214, fencing 216, doorways, 218, scissor lift 230, and boom lift 232. Model 200 may be generated or received by construction project data 100. While not shown in FIG. 2, construction project data 100 may further include a construction site model component, configured to generate a model of a construction site (e.g., site 210). Building 212 may be any type of building being constructed (e.g., an apartment complex, etc.). Foundation 214 may be any type of lower-portion building structure that transfers the building loads to the earth. Foundation 214 may be variations of concrete slabs that are either shallow or deep foundations.

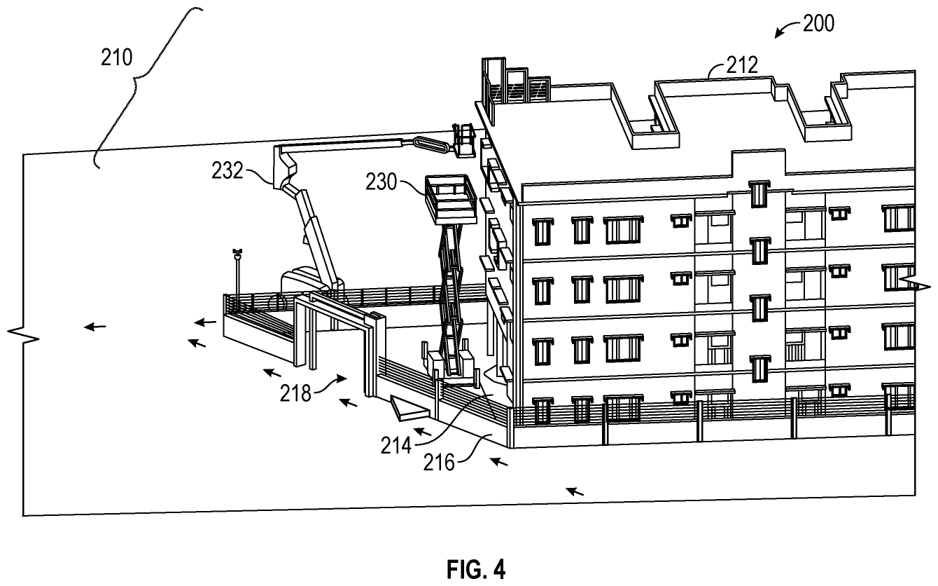

Referring now to FIG. 4, a two-dimensional model 400 of a construction site that may be generated by the BIM systems of FIGS. 1-2. Model 400 is shown to include various parts of model 200, fencing 216, doorways 218, scissor lift 230, and include boom lift 232. Model 400 may be incorporated partially or entirely into model 200. For example, model 400 may be a two-dimensional perspective of a portion of model 200.

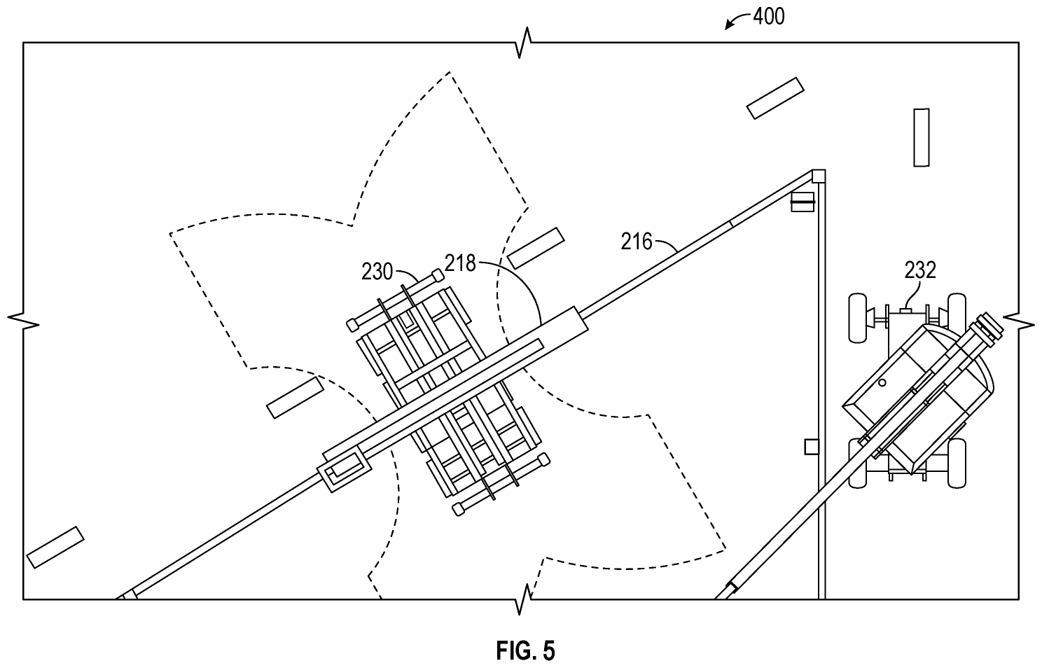

Referring now to FIG. 5, another embodiment of three-dimensional model 200 is shown, according to an exemplary embodiment. Model 200, as shown in FIG. 5, may be a different perspective of construction site 210. In an exemplary embodiment, a user may view model 200 from the perspective shown in FIG. 5 to better view the entrance into site 210. This may be done to determine if various equipment (e.g., scissor lift 230, boom lift 232, etc.) are capable of entering site 210 via doorways 218.

In an exemplary embodiment, processing within BIM system 10 (e.g., building information management device 20) determines whether scissor lift 230 can fit through doorway 218. Model 200 includes the operational parameters, weight, and dimensions of scissor lift 230, which may be provided by equipment data 110. Model 200 also includes the dimensions of the doorway, which may be provided by construction project data 100. Building information management device 10 may automatically determine whether scissor lift 230 fits though doorway 218 by comparing the dimensions of the scissor lift 230 with the dimensions of the doorway 218.

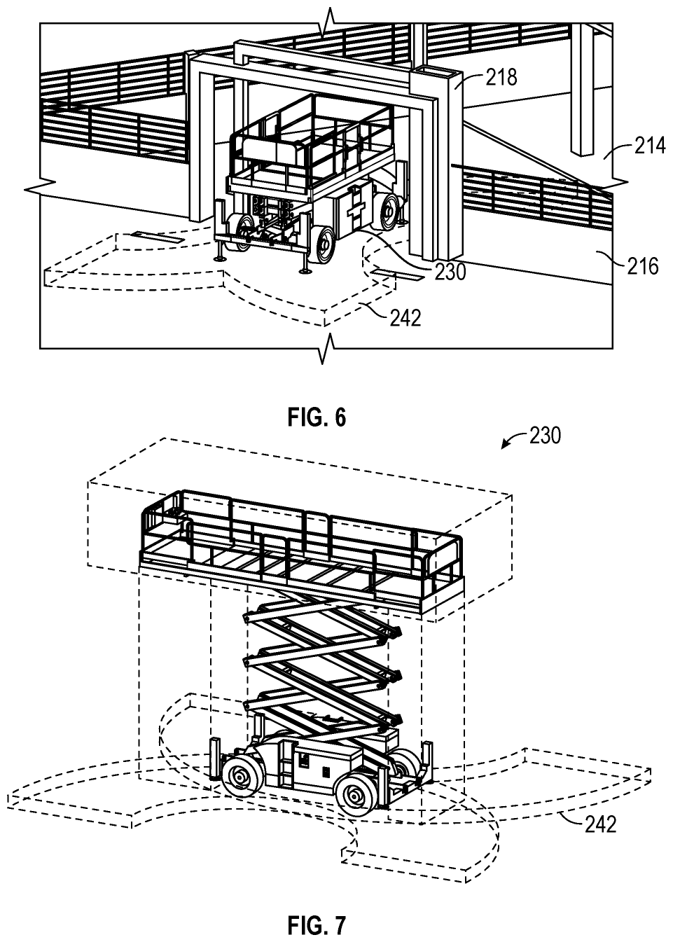

Referring now to FIG. 6, a detailed three-dimensional model of scissor lift 230 entering through doorway 218, according to an exemplary embodiment. The model of scissor lift 230 includes turning radius 242. The turning radius 242 may be illustrate to maximum amount of space required to turn, move, or rotate scissor lift 230. Data for turning radius 242 may be provided by equipment data 110, particularly equipment model data 112.

In an exemplary embodiment, processing within BIM system 10 (e.g., building information management device 20) determines whether scissor lift 230 can fit through doorway 218 while turning. Building information management device may determine that scissor lift 320 may fit through doorway 218 by driving in a linear direction (i.e., straight through doorway 218). However, in the event that scissor lift 230 is required to turn after entering/exiting doorway 218, building information management device 10 may automatically determine whether scissor lift 230 fits though doorway 218 by comparing the turning radius 242 with the dimensions of the doorway 218.

Referring now to FIG. 7, a three-dimensional model of scissor lift 230 is shown, according to an exemplary embodiment. FIG. 7 may illustrate a more detailed model of scissor lift 230 that includes a three-dimensional turning radius 242. Turning radius 242 of scissor lift 230 as shown in FIG. 7 may differ than turning radius 242 as shown in FIG. 6 such that turning radius 242 of FIG. 7 illustrates the maximum space required for turning scissor lift 230 in all directions.

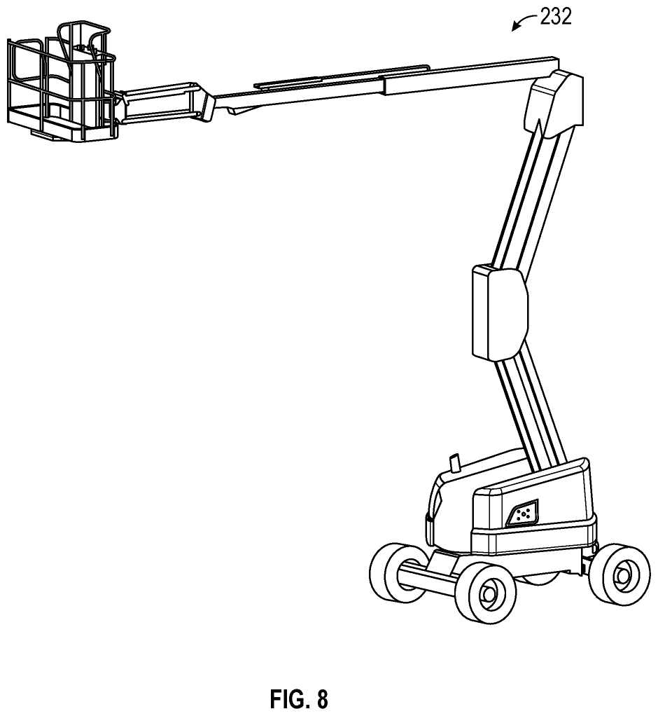

Referring now to FIG. 8, a three dimensional model of boom lift 232 is shown, according to an exemplary embodiment. Boom lift 232 may be another device with equipment data provided to building information management device 20 from equipment data 110. In an exemplary embodiment, building information management device 20 determines if boom lift 232 can fit through doorway 218, rather than scissor lift 230.

By way of example, the various models shown in FIGS. 3-8 may be dimensionally accurate such that the model can provide measurements (e.g., the width and heights of the doorways 218, etc.). Each element of the building 212, the foundation 214, and the fencing 216 may be individually interrogated to determine its specific properties (e.g., materials, size, etc.). By way of example, the foundation 214 may be interrogated to determine its load capacity (e.g., a point loading capacity, etc.). Specifically, a first piece of construction equipment is shown as scissor lift 230, and a second piece of construction equipment is shown as boom lift 232. When the construction equipment includes movable components (e.g., manipulators, outriggers, booms, etc.), the three-dimensional model may illustrate multiple positions of the movable components.

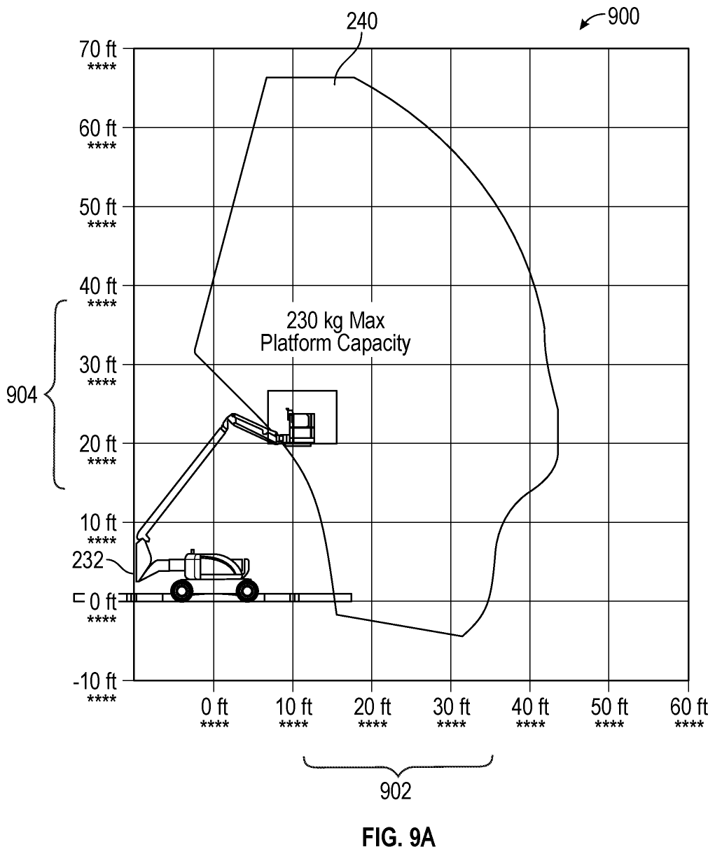

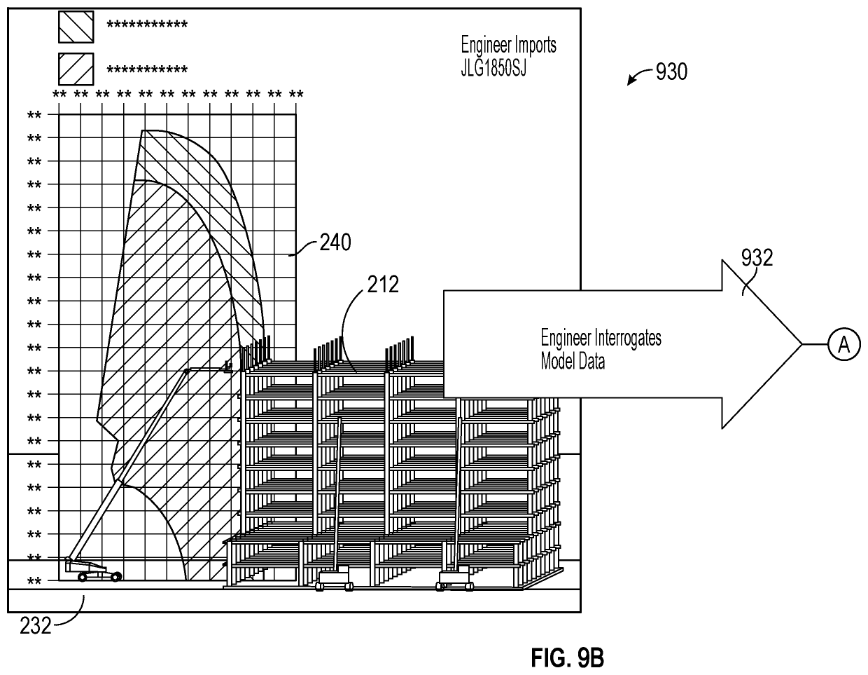

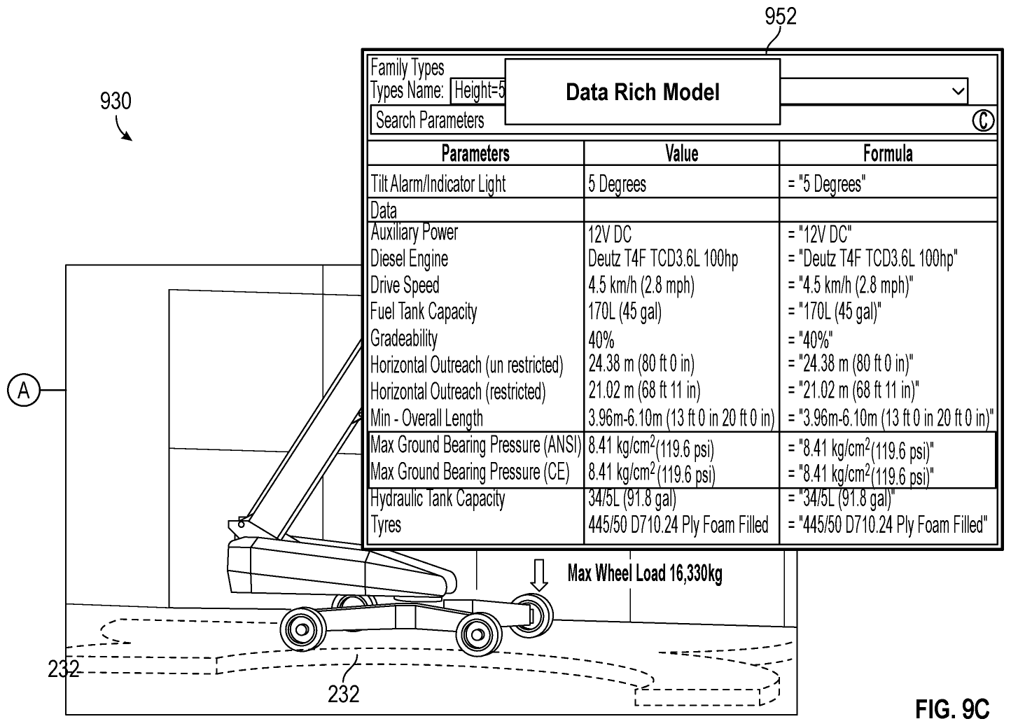

Referring now to FIG. 9A, a graph 900 that shows various operational parameters for boom lift 232 is shown, according to an exemplary embodiment. Graph 900 shows axis 902, 904 that represent the distance that the platform is capable of being located when boom lift 232 is in its current position. Graph 900 further shows the maximum platform capacity for boom lift 232 being 230 kg. The various operational parameters (e.g., platform capacity, location map for the platform of boom lift 232) may be elements of equipment data 110 provided to building information management device 20.

In an exemplary embodiment, a user may engage (e.g., click on) a widget of a user interface when viewing model 200 that allows the user to view operational parameters of boom lift 232, such as graph 900. This allows the user to view the details of certain equipment while simultaneously viewing the model of the construction site (e.g., site 210). In other embodiments, graph 900 is represented as a data structure and is used for generating modeling (e.g., recommendation data 130, model data 140) for a user.

In another exemplary embodiment, the graph 900 illustrates a work envelope 240 of the boom lift 232. Such a work envelope may be utilized to determine if the construction equipment can reach a required height or location. As shown in FIGS. 6 and 7, the model may additionally or alternatively illustrate a turning radius 242 of the scissor lift 230. The model may be dimensionally accurate to facilitate determining whether or not construction equipment can fit through a certain space or perform a certain task.

Referring now to FIG. 9B, a data model 930 for determining operational parameters of a boom lift is shown, according to an exemplary embodiment. Model 930 is shown to include work envelope 240 and building 212. Work envelope 240 may include some or all aspects of work envelope 240 as shown in FIG. 9A. Work envelope 240 may show the possible distances and locations of boom lift 232 in all three dimensions, as shown in FIG. 9B. Model 930 is further shown to include indicator 932. Indicator 932 states, “Engineer Interrogates Model Data.” In an exemplary embodiment, model 930 is viewed by a user (e.g., engineer, etc.) to determine whether boom lift 232 is applicable for certain tasks. The tasks may include fitting through doorway 218, as described with reference to FIGS. 3-8 above. In various embodiments, users may view model 930 (and similarly models 200, 400) to analyze models of the construction project and make building decisions based on the models generated.

Referring now to FIG. 9C, a data model 950 for viewing operational parameters of a boom lift is shown, according to an exemplary embodiment. Data model 950 is shown to include the model of boom lift 230 as shown in FIG. 7 and data window 952. Data window 952 may display various information regarding boom lift 232, including auxiliary power, drive speed, fuel tank capacity, gradeablilty, and length. The various information displayed in data window 952 may be provided by equipment data 110 to building information management device 20 to generate building models (e.g., model 400). In an exemplary embodiment, a user (e.g., engineer, etc.) determines whether boom lift 232 is applicable for certain tasks by viewing data window 952. The tasks may include fitting through doorway 218, as described with reference to FIGS. 3-8 above. In various embodiments, users may view model 930 (and similarly models 200, 400) to analyze models of the construction project and make building decisions based on the models generated.

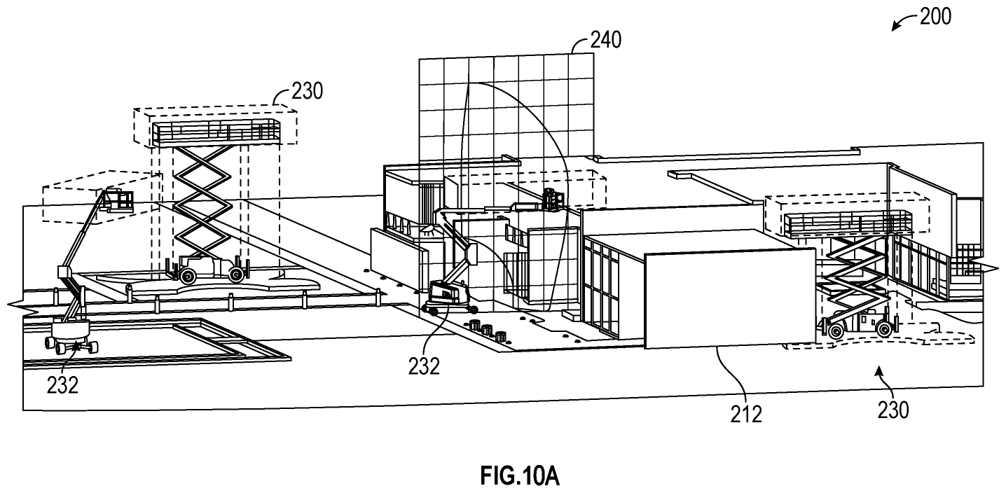

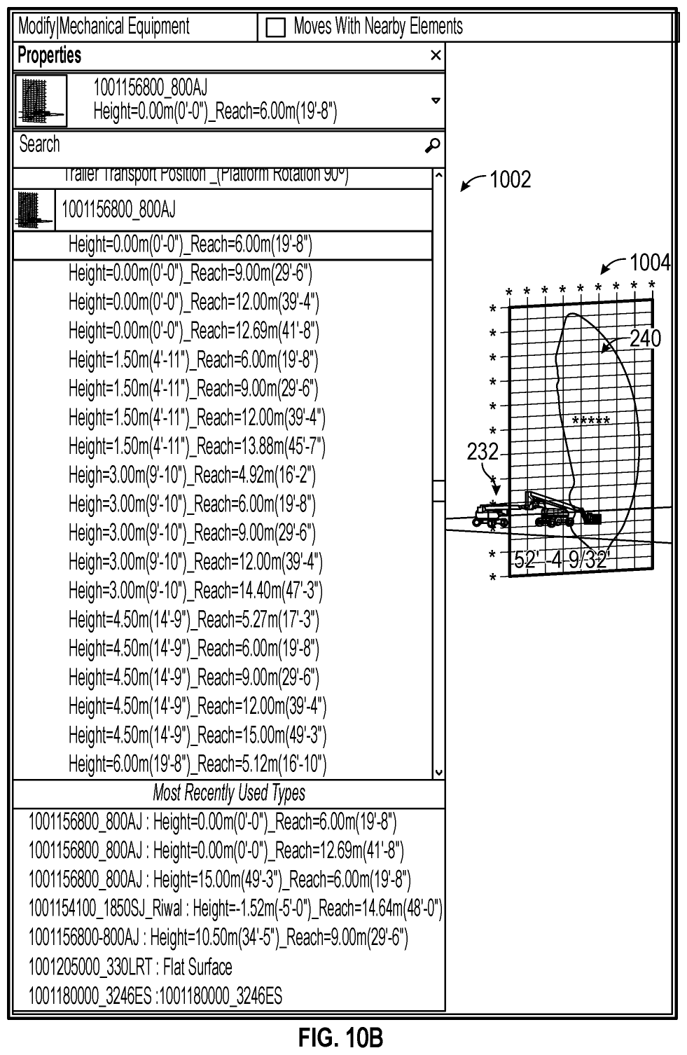

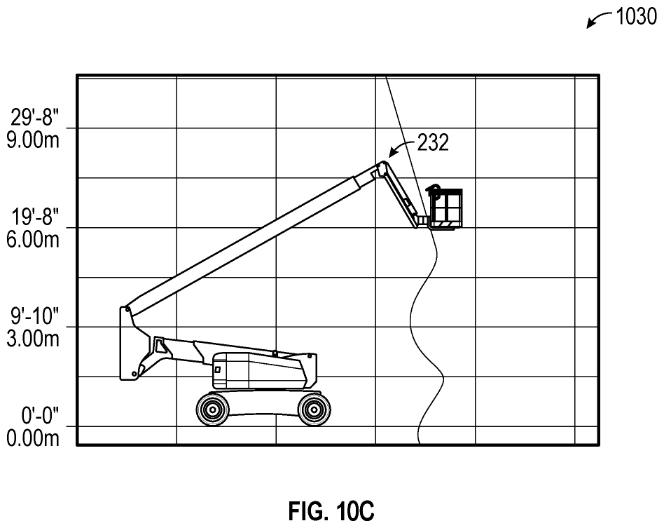

Referring now to FIG. 10A, another embodiment of three-dimensional model 200 is shown, according to an exemplary embodiment. Model 200, as shown in FIG. 10A, may be a different perspective of construction site 210. In an exemplary embodiment, a user may view model 200 from the perspective shown in FIG. 10A to better view operational parameters of boom lift 232 within building 212. This may be done to determine if boom lift 232 is capable of performing all required tasks (e.g., tasks provided by user input data 120 or construction project data 100) within building 212.

Referring now to FIG. 10B, components of a user interface and three-dimensional models generated by the BIM system 10. Components and models shown in FIG. 10B can be used to perform functions described in FIG. 10B. User interface component 1004 illustrates a model that includes work envelope 240 of the boom lift 232. Such a work envelope may be utilized to be utilized to determine the height, reach, or location for the construction equipment. A user may interact with user interface component 1002 to selected a desired point of height and reach.

User interface component 1002 illustrates a list containing information regarding construction equipment. User interface component 1002 may be populated with construction project data 100, equipment data 110, and/or model data 140. For example, a user may select a family table and/or reach and height dimensions for a piece of equipment using user interface component 1420. Upon interacting with user interface component 1002, model data 140 of the respective piece of equipment may automatically configure itself such that it meets the user's needs.

Referring now to FIG. 10C, user interface component 1030 illustrates a model of the boom lift 232. Component 1030 demonstrates the boom lift 232 adjusted to a new height and reach, in other words, the desired height and reach. The model of the boom lift 232 may be updated due to a change in the model data 140. In some embodiments, the required height, reach, and location may be determined using data received from user interface components 1002 and 1004.

### BIM Processes

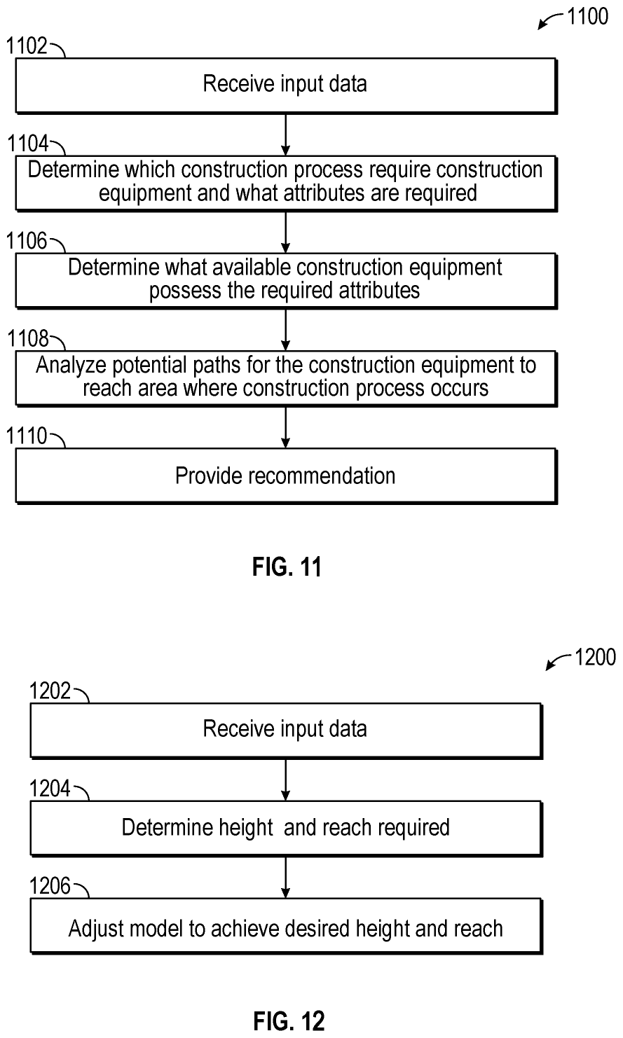

Referring now to FIG. 11, a process 1100 for linking construction equipment data with construction project data to determine a recommendation is shown, according to an exemplary embodiment. In an exemplary embodiment, process 1100 may be performed by building information management device 20.

Process 1100 is shown to include receiving input data (step 1102). The input data can include construction project data 100, equipment data 110, user input data 120, and/or other types of data not disclosed herein. The input data may be stored in memory (e.g., memory 26, server 30, etc.) and provided to building information management device 20 upon request from a user (e.g., via user input data 120) or automatically to generate modeling data (e.g., recommendation data 130, model data 140). In some embodiments, building information management device 20 updates data that is already stored within memory 26. By way of example, the building information management device 20 may regularly (e.g., once per hour, once per day, once per week, etc.) communicate with server 30 to determine if the equipment data 110 should be updated. The construction equipment data 110 may require updating when a new model of construction equipment is released by a manufacturer or when new or different information regarding a particular model of construction equipment is made available by a manufacturer. By regularly updating the construction equipment data 110, the building information management device 20 can ensure that it provides recommendations that are optimized to the current construction equipment availability.

Process 1100 is shown to include determining which construction processes require construction equipment and what attributes are required (step 1104). Specifically, using the input data, the building information management device 20 can determine what processes will require construction equipment in order to be completed and what attributes the construction equipment must possess to complete the construction process. By way of example, the construction project data 100 may include a listing of construction processes that will occur on certain dates. By way of another example, the user input data 120 may include a request to perform a certain construction process in a certain location. In one such example, a user (e.g., an architect) utilizes a user interface of a smartphone to request construction equipment recommendations for installing a light fixture in a certain location.

Process 1100 is shown to include determining what available construction equipment possess the required attributes (step 1106). In step 1106, the building information management device 20 again analyzes the input data. Specifically, the building information management device 20 utilizes the equipment data 110 to determine what available construction equipment possesses the attributes required to complete the construction process. By way of example, the equipment data 110 may indicate what construction equipment is available through a given manufacturer, through a given rental company, or within a given area. The building information management device 20 may determine which of this available equipment has the required attributes determined in step 1104.

Process 1100 is shown to include analyzing potential paths for the construction equipment to reach an area where the construction process occurs (step 1108). In step 1108, the building information management device 20 again analyzes the input data. Specifically, the building information management device 20 utilizes the construction project data 100 to determine if the construction equipment selected in steps 1104 and 1106 can successfully access the area in which the construction process occurs. In some situations, a building may have a finite number of paths along which an area can be accessed. By way of example, walls, doorways, and other obstacles may limit the number of paths. Of those paths, certain paths may not accommodate certain types of construction equipment. By way of example, a certain floor material may not be strong enough to accommodate the point loading that is exhibited by a certain type of construction equipment. By way of another example, a doorway or hallway may not be tall enough or wide enough for a certain piece of construction equipment to pass through. By way of another example, a path may bend more sharply than the turning radius of a piece of construction equipment, preventing movement of the construction equipment therethrough.

The attributes of the construction site that define the constraints of the paths may be provided in the construction project data 100. By way of example, the construction project data 100 may include the dimensions of rooms, doorways, and hallways. By way of example, the construction project data 100 may include the structural properties of the various support surfaces along a certain path. The corresponding attributes of the construction equipment may be provided in the equipment data 110. By way of example, the equipment data 110 may include the dimensions of the construction equipment, the turning radius of the construction equipment, and the loading of each wheel of the construction equipment on the supporting surface. By comparing the construction project data with the equipment data 110, the building information management device 20 may determine whether or not a piece of construction equipment is compatible with a certain path.

In one example, a user selects a path or a portion of a path for the construction equipment, and the building information management device 20 determines if the construction equipment can pass through that path. A user may select a particular doorway, hallway, room, or a combination thereof (e.g., through the user input data 120), and, in response, the building information management device 20 may determine which of the available pieces of construction equipment can travel along the selected path.

In another example, the building information management device 20 analyzes the construction project data 100 and identifies paths that lead to the area in which the construction process occurs. The building information management device 20 may identify a certain number of paths or may identify all of the possible paths that lead to the area in which the construction process occurs. Once the paths have been identified, the building information management device 20 may determine which of the available pieces of construction equipment can travel along each path.

Process 1100 is shown to include providing a recommendation (step 1110). In step 1110, the building information management device 20 provides recommendation data 130. The recommendation data 130 may be provided to a user, to another device, or otherwise utilized (e.g., automatically generating an equipment rental request that is sent to a rental company). By way of example, if the building information management device 20 identified available construction equipment that can reach the area where the corresponding construction occurs, the recommendation data 130 may include a listing of what construction equipment should be provided. The recommendation data 130 may additionally include time periods (e.g., dates and times) that certain construction equipment should be provided. These times may correspond to the times when the corresponding construction processes are scheduled to occur. By way of another example, if the building information management device 20 was unable to identify any available construction equipment that could reach the area in which the construction process occurs, the recommendation data 130 may include a recommendation describing how a certain area of the construction site might be modified (e.g., widened, reinforced, etc.) to permit the construction process to be completed. By way of another example, if the building information management device 20 was unable to identify any available construction equipment that could reach the area in which the construction process occurs, the recommendation data 130 may include a recommendation for how the schedule of the construction project may be modified to permit the construction process to be completed (e.g., placing a large appliance within a room before all of the walls are completed). By way of another example, if the building information management device 20 was unable to identify any available construction equipment that could reach the area in which the construction process occurs, the recommendation data 130 may identify other construction equipment that would permit the construction process to be completed (e.g., equipment located far from the construction site can complete the process). By way of another example, the recommendation data 130 may include a description of what path should be taken by the construction equipment to reach the area where the construction process occurs.

Machine learning or other advanced processing techniques may be utilized by the building information management device 20 throughout the process 1100 to improve the efficiency (e.g., increased speed, lowered processing requirements) of the process 1100 and/or to optimize the recommendation data 130. By way of example, during step 1108, the building information management device 20 may identify that a certain path (e.g., a wide, straight hallway) is frequently being selected to reach a certain area. The building information management device 20 may modify its control logic to default to using this path whenever that particular area is selected for a construction process, thereby reducing the processing power required to make a path selection. If that path does not meet the constraints of a certain piece of construction equipment, however, the building information management device 20 may determine if another path can be used by the construction equipment.

In another embodiment, the building information management device 20 utilizes a neural network to minimize the time associated with moving a piece of construction equipment to a certain area. By way of example, the building information management device 20 may have the option to select between a variety of different models of construction equipment, a variety of different paths through the building, and a variety of drop-off points for the construction equipment at the construction site. The building information management device 20 may use a neural network that is trained to select the type of equipment, the path, and the drop-off point to minimize the distance travelled by the construction equipment.

Referring now to FIG. 12, the building information management device 20 is configured to complete a process 1200 for receiving input data and automatically configuring a building information model (BIM). Process 1200 can simplify the building information modeling (BIM) experience for a user, particularly a user with limited knowledge of the equipment parameters.

Process 1200 is shown to include receiving input data (step 1202). In step 1202, the building information management device 20 is configured to receive input data. The input data can include the construction project data 100, the equipment data 110, the user input data 120, and/or other types of data. The input data may be stored (e.g., within the memory 26). For example, the input data received may include a desired reach and height point needed to achieve a particular function. In certain embodiments, the input data may include selection of a family of equipment. By way of example, the family of equipment can be a group of equipment data 110 that have attributes in common. In some embodiments, the input data received may include dimensions for reach and height of a piece of equipment.

Process 1200 is shown to include determining height and read required (step 1204). In step 1204, the building information management device 20 is configured to determine height and reach required for a piece of equipment to perform the desired function. The building information management device 20 may use input data received in step 11102 to determine the required height and reach. For example, the building information management device 20 may use a necessary reach and height point with the reach and height dimensions for a selected piece of equipment to determine the height and reach required. The building information management device 20 may use construction project data 100, the equipment data 100, the user input data 120, input data received in step 1202, and/or other types of data. Determining the height and reach required may be calculated using algorithms and/or machine learning.

Process 1200 is shown to include adjusting a model to achieve desired height and reach (step 1206). In step 1206, the building information management device 20 is configured to re-configure model data 140 to achieve the desired height and reach (e.g., as determined in step 1202 and/or step 1204). The building information management device 20 may automatically update one or more attributes of model data 140 to achieve the desired height and reach. For example, the building information management device 20 may automatically adjust the boom extensions and/or boom angles attributes in model data 140 for a lift device.

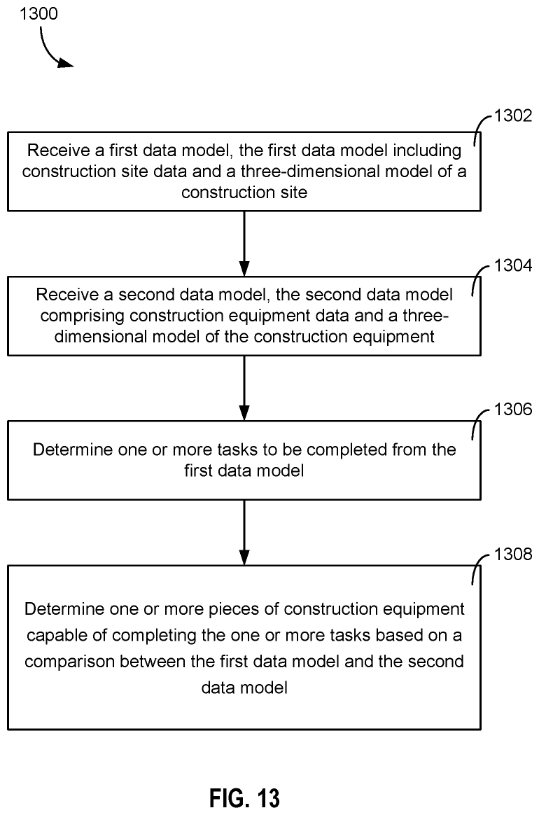

Referring now to FIG. 13, a process 1300 for automatically configuring a BIM system is shown, according to an exemplary embodiment. Process 1300 may be performed by various processing circuitry within BIM system 10 as shown in FIGS. 1 and 2, such as building information management device 20.

Process 1300 is shown to include receiving a first data model, the first data model including construction site data and a three-dimensional model of a construction site (step 1302). Building information management device may receive a first data model (e.g., data, information, etc.) from construction project data 100. Step 1302 may include receiving various data structures, objects, or any other kind of information relating to modeling.

In an exemplary embodiment, step 1302 includes receiving construction site data that includes information relating to at least one of the budget, status of a construction site, or steps to complete a project at the construction site. Step 1302 may also include receiving a three-dimensional model comprising one or more designs of the construction site that can be viewed and edited via a user interface. The various information received in step 1302 may be stored on server 30, provided by users via devices 40, or provided by construction project data 100, or any combination thereof.

Process 1300 is shown to include receiving a second data model, wherein the second data model includes construction equipment data and a three-dimensional model of the construction equipment (step 1304). In an exemplary embodiment, step 1304 includes receiving construction equipment data that includes one or more information tables relating to a plurality of construction equipment. The information tables include at least one of the dimensions, weight capacities, or physical properties of the plurality of construction equipment. Step 1304 may include receiving a three-dimensional mode of the construction equipment comprising one or more designs of the construction site that can be viewed and edited via a user interface. The various information received in step 1304 may be stored on server 30, provided by users via devices 40, or provided by construction project data 100, or any combination thereof.

Process 1300 is shown to include determining one or more tasks to be completed from the first data model (step 1306). Tasks, as described herein, may refer to various steps or actions that need to be taken to advance the progress of a project at the construction site. In an exemplary embodiment, step 1306 includes determining that the first data model includes at least one of the dimensions, weight capacities, or physical properties of a plurality of construction components (e.g., walls, foundations, etc.) at the construction site. Step 1306 may also include receiving, via a device (e.g., device 40), instructions to alter one of the plurality of construction components and generating one or more tasks to be completed to alter one of the plurality of construction components. For example, after modeling the pouring of the foundation within model 200, building information management device 20 may determine that framing the walls is a task that needs to be completed next.

Process 1300 is shown to include determining one or more pieces of construction equipment capable of completing the one or more tasks based on a comparison between the first data model and the second data model (step 1308). In an exemplary embodiment, step 1308 includes comparing equipment model data 112 (e.g., information tables, etc.) of the second data model (e.g., equipment data 110) to the one or more tasks to determine if the information tables indicate that the plurality of construction equipment can complete the one or more tasks.

### CONFIGURATION OF EXEMPLARY EMBODIMENTS

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

The hardware and data processing components used to implement the various processes, operations, illustrative logics, logical blocks, modules and circuits described in connection with the embodiments disclosed herein may be implemented or performed with a general purpose single- or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some embodiments, particular processes and methods may be performed by circuitry that is specific to a given function. The memory (e.g., memory, memory unit, storage device) may include one or more devices (e.g., RAM, ROM, Flash memory, hard disk storage) for storing data and/or computer code for completing or facilitating the various processes, layers and modules described in the present disclosure. The memory may be or include volatile memory or non-volatile memory, and may include database components, object code components, script components, or any other type of information structure for supporting the various activities and information structures described in the present disclosure. According to an exemplary embodiment, the memory is communicably connected to the processor via a processing circuit and includes computer code for executing (e.g., by the processing circuit or the processor) the one or more processes described herein.

The present disclosure contemplates methods, systems and program products on any machine-readable media for accomplishing various operations. The embodiments of the present disclosure may be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general purpose computer, special purpose computer, or special purpose processing machines to perform a certain function or group of functions.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It is important to note that the construction and arrangement of the various BIM systems (e.g., BIM system 10) as shown in the various exemplary embodiments is illustrative only. Additionally, any element disclosed in one embodiment may be incorporated or utilized with any other embodiment disclosed herein. For example, the model 400 of the exemplary embodiment shown in FIG. 5 may be incorporated in the model 200 of the exemplary embodiment shown in FIG. 3. Although only one example of an element from one embodiment that can be incorporated or utilized in another embodiment has been described above, it should be appreciated that other elements of the various embodiments may be incorporated or utilized with any of the other embodiments disclosed herein.

What is claimed is:

1. A method for automatically configuring a building information model (BIM), the method comprising:
receiving a first data model, the first data model comprising construction site data and a three-dimensional model of a construction site;
receiving a second data model, the second model comprising construction equipment data and a three-dimensional model of the construction equipment;
determining one or more tasks to be completed from the first data model;
determining one or more pieces of construction equipment capable of completing the one or more tasks based on a comparison between the first data model and the second data model.

2. The method of claim 1, wherein determining one or more tasks to be completed from the first data model comprises:
determining that the first data model includes at least one of the dimensions, weight capacities, or physical properties of a plurality of construction components at the construction site;
receiving, via a user device, instructions to alter one of the plurality of construction components; and
generating one or more tasks to be completed to alter one of the plurality of construction components.

3. The method of claim 1, further comprising:
updating a user interface to indicate that one or more pieces of construction equipment is capable of completing the one or more tasks; and
upon completion of the one or more tasks, updating the user interface to indicate completion of the one or more tasks.

4. The method of claim 1, wherein receiving the first data model comprises:
receiving construction site data comprising information relating to at least one of the budget, status of a construction site, or steps to complete a project at the construction site; and
receiving a three-dimensional model comprising one or more designs of the construction site that can be viewed and edited via a user interface.

5. The method of claim 1, wherein receiving the second data model comprises:
receiving construction equipment data comprising one or more information tables relating to a plurality of construction equipment, the information tables comprising at least one of the dimensions, weight capacities, or physical properties of the plurality of construction equipment; and
receiving a three-dimensional mode of the construction equipment comprising one or more designs of the construction site that can be viewed and edited via a user interface.

6. The method of claim 5, wherein determining one or more pieces of construction equipment capable of completing the one or more tasks comprises:
comparing the information tables of the second data model to the one or more tasks to determine if the information tables indicate that the plurality of construction equipment can complete the one or more tasks.

7. The method of claim 1, further comprising:
receiving the first data model and the second data model in a building information management device;
determining, via the building information management device, the one or more pieces of construction equipment capable of completing the one or more tasks based on a comparison between the first data model and the second data model; and
providing, via the building information management device, one or more recommendations to a user interface.

8. A building information model (BIM) system for automatically configuring a building model, the system comprising:
a processing circuit comprising one or more processors and memory storing instructions that, when executed by the one or more processors, cause the one or more processors to perform operations comprising:
receiving a first data model, the first data model comprising construction site data and a three-dimensional model of a construction site;
receiving a second data model, the second model comprising construction equipment data and a three-dimensional model of the construction equipment;
determining one or more tasks to be completed from the first data model;
determining one or more pieces of construction equipment capable of completing the one or more tasks based on a comparison between the first data model and the second data model.

9. The system of claim 8, wherein determining one or more tasks to be completed from the first data model comprises:
determining that the first data model includes at least one of the dimensions, weight capacities, or physical properties of a plurality of construction components at the construction site;
receiving, via a user device, instructions to alter one of the plurality of construction components; and
generating one or more tasks to be completed to alter one of the plurality of construction components.

10. The system of claim 8, wherein the processing circuit is further configured to:
updating a user interface to indicate that one or more pieces of construction equipment is capable of completing the one or more tasks; and
upon completion of the one or more tasks, updating the user interface to indicate completion of the one or more tasks.

11. The system of claim 8, wherein receiving the first data model comprises:
receiving construction site data comprising information relating to at least one of the budget, status of a construction site, or steps to complete a project at the construction site; and
receiving a three-dimensional model comprising one or more designs of the construction site that can be viewed and edited via a user interface.

12. The system of claim 8, wherein receiving the second data model comprises:
receiving construction equipment data comprising one or more information tables relating to a plurality of construction equipment, the information tables comprising at least one of the dimensions, weight capacities, or physical properties of the plurality of construction equipment; and
receiving a three-dimensional mode of the construction equipment comprising one or more designs of the construction site that can be viewed and edited via a user interface.

13. The system of claim 12, wherein determining one or more pieces of construction equipment capable of completing the one or more tasks comprises:
comparing the information tables of the second data model to the one or more tasks to determine if the information tables indicate that the plurality of construction equipment can complete the one or more tasks.

14. The system of claim 8, wherein the processing circuit is further configured to:
receiving the first data model and the second data model in a building information management device;
determining, via the building information management device, the one or more pieces of construction equipment capable of completing the one or more tasks based on a comparison between the first data model and the second data model; and
providing, via the building information management device, one or more recommendations to a user interface.

15. A building information management device for automatically configuring a building model, the device comprising:
a processing circuit comprising one or more processors and memory storing instructions that, when executed by the one or more processors, cause the one or more processors to perform operations comprising:
receiving a first data model, the first data model comprising construction site data and a three-dimensional model of a construction site;
receiving a second data model, the second model comprising construction equipment data and a three-dimensional model of the construction equipment;
determining one or more tasks to be completed from the first data model;
determining one or more pieces of construction equipment capable of completing the one or more tasks based on a comparison between the first data model and the second data model.

16. The device of claim 15, wherein determining one or more tasks to be completed from the first data model comprises:
determining that the first data model includes at least one of the dimensions, weight capacities, or physical properties of a plurality of construction components at the construction site;
receiving, via a user device, instructions to alter one of the plurality of construction components; and
generating one or more tasks to be completed to alter one of the plurality of construction components.

17. The device of claim 15, wherein the processing circuit is further configured to:
updating a user interface to indicate that one or more pieces of construction equipment is capable of completing the one or more tasks; and
upon completion of the one or more tasks, updating the user interface to indicate completion of the one or more tasks.

18. The device of claim 15, wherein receiving the first data model comprises:
receiving construction site data comprising information relating to at least one of the budget, status of a construction site, or steps to complete a project at the construction site; and
receiving a three-dimensional model comprising one or more designs of the construction site that can be viewed and edited via a user interface.

19. The device of claim 15, wherein receiving the second data model comprises:
receiving construction equipment data comprising one or more information tables relating to a plurality of construction equipment, the information tables comprising at least one of the dimensions, weight capacities, or physical properties of the plurality of construction equipment; and
receiving a three-dimensional mode of the construction equipment comprising one or more designs of the construction site that can be viewed and edited via a user interface.

20. The device of claim 19, wherein determining one or more pieces of construction equipment capable of completing the one or more tasks comprises:
comparing the information tables of the second data model to the one or more tasks to determine if the information tables indicate that the plurality of construction equipment can complete the one or more tasks.
